(19) United States
(12) Patent Application Publication
(10) Pub. No.: US 2022/0317557 A1
(43) Pub. Date: Oct. 6, 2022

(54) OPTICAL PROXIMITY CORRECTION METHOD AND APPARATUS

(71) Applicant: CHANGXIN MEMORY TECHNOLOGIES, INC., Hefei, Anhui (CN)

(72) Inventor: HSIN-TING CHEN, Hefei (CN)

(73) Assignee: CHANGXIN MEMORY TECHNOLOGIES, INC., Hefei, Anhui (CN)

(21) Appl. No.: 17/310,883

(22) PCT Filed: Mar. 29, 2021
(86) PCT No.: PCT/CN2021/083594

§ 371 Date: Aug. 27, 2021

(30) Foreign Application Priority Data
Apr. 3, 2020 (CN) 202010260048.1

(51) Int. Cl. G03F 1/36

(52) U.S. Cl. CPC G03F 1/36

(57) ABSTRACT

An optical proximity correction method includes: obtaining a test mask; obtaining wafer data under current photolithography conditions by the test mask; establishing an optical proximity correction model and a process variation band model by the wafer data; correcting a target pattern according to the optical proximity correction model and the process variation band model to obtain a first correction pattern and a second correction pattern respectively; calculating a difference value between a first simulation contour of the first correction pattern and a second simulation contour of the second correction pattern; and adjusting a correction mode for the target pattern according to the difference value.

### CROSS-REFERENCE TO RELATED APPLICATIONS

The present disclosure claims priority to Chinese Patent Application No. 202010260048.1, entitled “OPTICAL PROXIMITY CORRECTION METHOD AND APPARATUS”, filed on Apr. 3, 2020, which is incorporated herein by reference in its entirety.

### TECHNICAL FIELD

The present disclosure relates to the field of semiconductor manufacturing, and in particular, to an optical proximity correction method and an apparatus.

### BACKGROUND

Due to the diffraction effect of ultraviolet light, the images exposed on the photoresist on the silicon wafer surface are distorted, and the quality of images is finally reduced. This is called optical proximity effect (OPE). The main pattern distortion caused by OPE manifests as line width deviation, shorter lines, rounded corners, etc.

By appropriately modifying the patterns on the mask to compensate for this effect, patterns the same as the design patterns can be obtained on the silicon wafer. This correction is called optical proximity correction (OPC). The existing OPC is mainly to ensure that the critical size of the silicon wafer is close to the design target and to minimize the edge placement error (EPE). However, in this case, it may be impossible to ensure that the size of the photolithography process window (PW) conforms to the range required by the manufacturing process. As a result, it is impossible to guarantee the quality of the process.

### SUMMARY

Embodiments of the present disclosure provide an optical proximity correction method and an apparatus. The optical proximity correction method considers the possible variations caused by the process variation band during the correction, enlarges the photolithography process window, and improves the product yield.

In a first aspect, an embodiment of the present disclosure provides an optical proximity correction method, comprising:

obtaining a test mask;

obtaining wafer data under current photolithography conditions by the test mask;

establishing an optical proximity correction model and a process variation band model by the wafer data;

correcting a target pattern according to the optical proximity correction model and the process variation band model to obtain a first correction pattern and a second correction pattern respectively;

calculating a difference value between a first simulation contour of the first correction pattern and a second simulation contour of the second correction pattern; and

adjusting a correction mode for the target pattern according to the difference value.

In an embodiment, the adjusting the correction mode for the target pattern according to the difference value comprises:

setting a threshold;

correcting the target pattern by the optical proximity correction model, if the difference value is less than or equal to the threshold; and

adjusting the optical proximity correction model, and correcting the target pattern by the adjusted optical proximity correction model, if the difference value is greater than the threshold.

In an embodiment, the adjusting the optical proximity correction model comprises:

adjusting the optical proximity correction model by changing a sub-resolution assistant feature and/or re-sizing the pattern, until the difference value between the first simulation contour of the first correction pattern and the second simulation contour of the second correction pattern, obtained by the adjusted optical proximity correction model, is less than or equal to the threshold.

In an embodiment, the method further comprises:

adjusting a target value of the target pattern, if the difference value between the first simulation contour of the first correction pattern and the second simulation contour of the second correction pattern, obtained by the optical proximity correction model after multiple adjustments, is still greater than the threshold; and

correcting the optical proximity correction model again by the adjusted target value, until the difference value between the first simulation contour of the first correction pattern and the second simulation contour of the second correction pattern, obtained by the adjusted optical proximity correction model, is less than or equal to the threshold.

In an embodiment, the adjusting a target value of the target pattern comprises:

calculating the positional relationships between the target pattern and an upper pattern and/or a lower pattern; and

adjusting the target value according to the positional relationships.

In an embodiment, the calculating the positional relationships between the target pattern and an upper pattern and/or a lower pattern comprises:

calculating distances between the boundary of the target pattern and the boundary of the upper pattern and/or the lower pattern overlapping with the target pattern.

In an embodiment, the calculating the positional relationships between the target pattern and an upper pattern and/or a lower pattern further comprises:

calculating the distances between the boundary of the target pattern and the boundary of a pattern close to the upper pattern and/or the lower pattern overlapping with the target pattern.

In an embodiment, the adjusting the correction mode for the target pattern according to the difference value further comprises:

obtaining a simulation process window of the first correction pattern and a simulation process window of the second correction pattern; and

correcting the pattern by the optical proximity correction model, if the simulation process window of the first correction pattern is greater than or equal to the simulation process window of the second correction pattern and the difference value is less than or equal to a set threshold; and

correcting the pattern by the process variation band model, if the simulation process window of the first correction pattern is less than the simulation process window of the second correction pattern and the difference value is less than or equal to a set threshold.

In an embodiment, the adjusting the correction mode for the target pattern according to the difference value further comprises:

obtaining a simulation process window of the first correction pattern and a simulation process window of the second correction pattern; and

adopting the correction mode of the first simulation profile and the second simulation profile which one is closer to the target value of the target pattern, if the simulation process window of the first correction pattern is greater than or equal to the simulation process window of the second correction pattern, and the difference value is greater than a set threshold.

In an embodiment, the establishing the optical proximity correction model and the process variation band model by the wafer data comprises:

obtaining optical system relevant parameters, mask relevant parameters, photolithography target film layer relevant parameters and wafer data under the current photolithography conditions to establish the optical proximity correction model; and

establishing the process variation band model according to the wafer data of a focus energy matrix and data of the current photolithography conditions.

In an embodiment, the wafer data of the focus energy matrix comprises wafer data obtained by an exposure and focal depth matrix, which is formed by taking the standard exposure and the standard focal depth as the center, and then respectively extending in positive and negative directions by a preset exposure step size and a preset focal depth step size.

In a second aspect, an embodiment of the present disclosure provides an optical proximity correction apparatus, comprising:

a mask obtaining module, configured to obtain a test mask;

a data obtaining module, configured to obtain wafer data under current photolithography conditions by the test mask;

a model establishment module, configured to establish an optical proximity correction model and a process variation band model by the wafer data;

a correction module, configured to correct a target pattern according to the optical proximity correction model and the process variation band model to obtain a first correction pattern and a second correction pattern respectively;

a calculation module, configured to calculate a difference value between a first simulation contour of the first correction pattern and a second simulation contour of the second correction pattern; and

an adjustment module, configured to adjust the correction mode for the target pattern according to the difference value.

By the optical proximity correction method according to the embodiments of the present disclosure, a test mask is fabricated, and photolithography tests are performed by using the test mask; wafer data under current photolithography conditions is obtained by the test mask; an optical proximity correction model and a process variation band model are established by the wafer data; a target pattern is corrected according to the optical proximity correction model and the process variation band model to obtain a first correction pattern and a second correction pattern respectively; a difference value between a first simulation contour of the first correction pattern and a second simulation contour of the second correction pattern is calculated; and the correction mode for the target pattern is adjusted according to the difference value. The possible variations caused by the process variation band are considered during the optical proximity correction, the insufficient photolithography process window during the existing correction is overcome, the photolithography process window is enlarged, and the product yield is improved.

### BRIEF DESCRIPTION OF THE DRAWINGS

FIG. 1 is a schematic flowchart of an optical proximity correction method according to an embodiment of the present disclosure;

FIG. 2 is a schematic diagram of ideal contours of the target pattern and the photolithography pattern under standard conditions according to an embodiment of the present disclosure;

FIG. 3 is a schematic diagram of ideal contours of the target pattern and the photolithography pattern in FEM according to an embodiment of the present disclosure;

FIG. 4 is a schematic diagram of actual contours of the target pattern and the photolithography pattern in FEM according to an embodiment of the present disclosure;

FIG. 5 is a schematic flowchart of a correction mode for adjustment of the target pattern according to an embodiment of the present disclosure;

FIG. 6 is a schematic structure diagram of a hole-shaped target pattern according to an embodiment of the present disclosure; and

FIG. 7 is a structure diagram of an optical proximity correction apparatus according to an embodiment of the present disclosure.

### DETAILED DESCRIPTION

The present disclosure will be further described below with reference to the accompanying drawings by embodiments. It may be understood that the specific embodiments to be described herein are only used to explain the present disclosure, rather than limiting the present disclosure. In addition, it should be noted that, for ease of description, only a part of the structure related to the present disclosure is shown in the accompanying drawings instead of all of the structure.

The terms used in the embodiments of the present disclosure are only for the purpose of describing specific embodiments, and are not intended to limit the present disclosure. It should be noted that terms such as “upper”, “lower”, “left”, “right” used in the embodiments of the present disclosure are provided from the angle shown in the drawings, and should not be construed as limiting the embodiments of the present disclosure. In addition, in the context, it should be understood that, when it is mentioned that an element is formed “on” or “below” another element, it may be formed directly “on” or “below” another element, and also it may be formed “on” or “below” another element indirectly through an intermediate element. Terms such as “first” and “second” are just used for the purpose of description. They are just used to distinguish different components, without indicating any order, quantity or importance. For a person of ordinary skill in the art, the specific meaning of the above-mentioned terms in the present disclosure may be understood in specific circumstances.

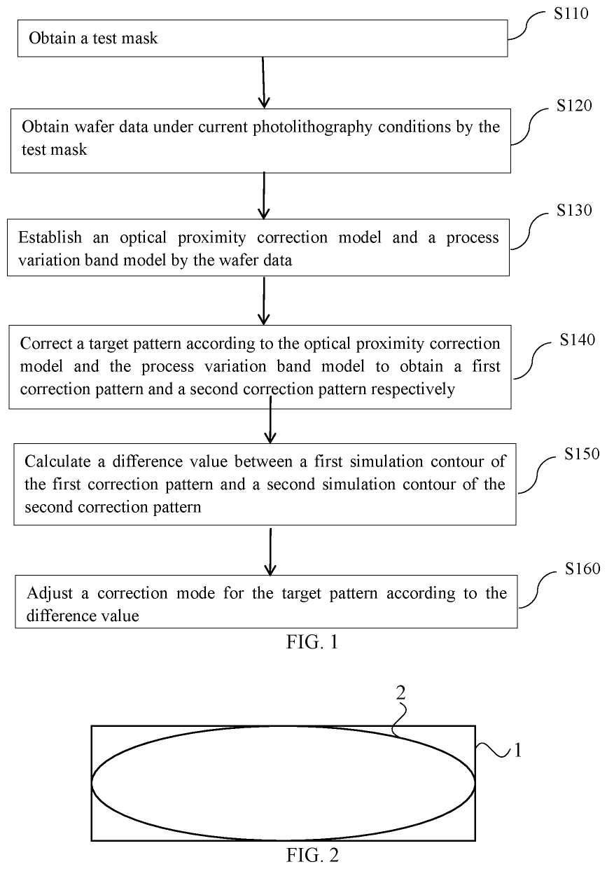

FIG. 1 is a schematic flowchart of an optical proximity correction method according to an embodiment of the present disclosure. This embodiment may be applied to the optical proximity correction in the photolithography process. The method may be executed by an optical proximity correction apparatus. The optical proximity correction apparatus may be implemented by software and/or hardware. For example, the optical proximity correction apparatus may be configured in a computer device. As shown in FIG. 1, the optical proximity correction method comprises the following steps.

S110: A test mask is obtained.

In this embodiment, the test mask may comprise multiple types of test patterns, for example line test patterns, hole test patterns, and the like. The test mask is designed according to the design rules of the test pattern. For example, for the line test pattern, the design rules comprise the target line width of the line test pattern, the target length of the line test pattern, and the target spacing between the line test patterns. In an embodiment, the method further comprises the step of fabricating a test mask.

S120: Wafer data under current photolithography conditions is obtained by the test mask.

By the test mask fabricated in the previous step, under the current photolithography conditions, for example the current lighting mode, photoresist type, photoresist thickness and other selected conditions, the wafer exposure is performed. Various data on the wafer formed by exposure by using the test mask may be collected.

S130: An optical proximity correction model and a process variation band model are established by the wafer data.

In an embodiment, establishing the optical proximity correction model and the process variation band model by the wafer data comprises:

obtaining optical system relevant parameters, mask relevant parameters, photolithography target film layer relevant parameters and wafer data under the current photolithography conditions to establish the optical proximity correction model.

The relevant parameters of the optical system comprise the wavelength of the light source, the numerical aperture NA, the partial coherence factor sigma, etc. The relevant parameters of the mask comprise the type, shape, and size of the test pattern on the mask. The relevant parameters of the photolithography target film layer comprise the stacking relationship, thickness, etc., of different film layers on the exposed wafer. An optical proximity correction (OPC) model is established according to these parameters and wafer data, and then simulated and corrected. The contour of the photolithography pattern, which is formed on the wafer by the exposure of the corrected pattern, may be simulated by the optical proximity correction model, and according to the simulation result, the standard exposure and the standard focal depth may be selected as standard conditions for correction. Exemplarily, FIG. 2 is a schematic diagram of ideal contours of the target pattern and the photolithography pattern under standard conditions according to an embodiment of the present disclosure, wherein the rectangle 1 is the contour of the target pattern and the ellipse 2 is the contour of the photolithography pattern.

| | | | | |
|---|---|---|---|---|
| (24.5, 0.1) | (24.5, 0.15) | (24.5, 0.2) | (24.5, 0.25) | (24.5, 0.3) |
| (24.75, 0.1) | (24.75, 0.15) | (24.75, 0.2) | (24.75, 0.25) | (24.75, 0.3) |
| (25, 0.1) | (25, 0.15) | (25, 0.2) | (25, 0.25) | (25, 0.3) |
| (25.25, 0.1) | (25.25, 0.15) | (25.25, 0.2) | (25.25, 0.25) | (25.25, 0.3) |
| (25.5, 0.1) | (25.5, 0.15) | (25.5, 0.2) | (25.5, 0.25) | (25.5, 0.3) |

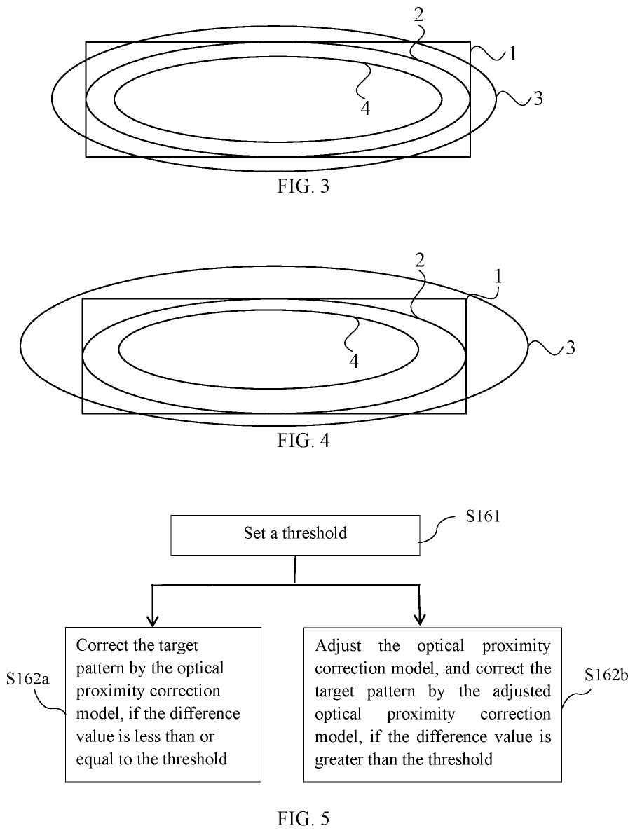

The contour is simulated by photolithography under given focal depth and exposure. The process variation band (PV band) is defined as the area between the outer contour and the inner contour (that is, the area between the ellipse 3 and the ellipse 4 in FIG. 3). In actual situations, due to the existence of many system or random variation sources, FIG. 4 is a schematic diagram of actual contours of the target pattern and the photolithography pattern in FEM according to an embodiment of the present disclosure, where the rectangle 1 is the contour of the target pattern, the ellipse 2 is the contour of the photolithography pattern under standard conditions, the ellipse 3 is the contour of the photolithography pattern under the positive defocus or overexposure condition, and the ellipse 4 is the contour of the photolithography pattern under the negative defocus or underexposure condition. According to the wafer data of the FEM and data of the current photolithography conditions, a process variation band model may be established. Specifically, the wafer is exposed under the exposure conditions defined by the FEM to obtain real wafer data under different exposures and focal depths, and the process variation band model is established by using the wafer data and photolithography conditions.

S140: A target pattern is corrected according to the optical proximity correction model and the process variation band model to obtain a first correction pattern and a second correction pattern respectively.

In this embodiment, the target pattern is corrected according to the optical proximity correction model and the process variation band model, respectively, to obtain a first correction pattern and a second correction pattern, as well as the first simulation contour of the first correction pattern (similar to FIG. 3) and the second simulation contour of the second correction pattern (similar to FIG. 4).

S150: A difference value between the first simulation contour of the first correction pattern and the second simulation contour of the second correction pattern is calculated.

S160: The correction mode for the target pattern is adjusted according to the difference value.

FIG. 5 is a schematic flowchart of a correction mode for adjustment of the target pattern according to an embodiment of the present disclosure. Referring to FIG. 5, in an embodiment, adjusting the correction mode for the target pattern according to the difference value comprises:

S161: setting a threshold;

S162a: correcting the target pattern by the optical proximity correction model, if the difference value is less than or equal to a threshold; and

S162b: adjusting the optical proximity correction model, and correcting the target pattern by the adjusted optical proximity correction model, if the difference value is greater than the threshold.

During the specific implementation, the threshold may be set according to actual photolithography conditions, and the specific value is not limited in the embodiments of the present disclosure. For example, the threshold is 10 nm, 5 nm, 3 nm, or 1 nm.

By the technical solution of this embodiment, a test mask is fabricated, and photolithography tests are performed by using the test mask; wafer data under current photolithography conditions is obtained by the test mask; an optical proximity correction model and a process variation band model are established by the wafer data; a target pattern is corrected according to the optical proximity correction model and the process variation band model to obtain a first correction pattern and a second correction pattern respectively; a difference value between a first simulation contour of the first correction pattern and a second simulation contour of the second correction pattern is calculated; and the correction mode for the target pattern is adjusted according to the difference value. The possible variations caused by the process variation band are considered during the optical proximity correction, the insufficient photolithography process window during the existing correction is overcome, the photolithography process window is enlarged, and the product yield is improved.

On the basis of the above technical solution, in an embodiment, adjusting the optical proximity correction model comprises:

adjusting the optical proximity correction model by changing a sub-resolution assistant feature and/or re-sizing the pattern, until the difference value between the first simulation contour of the first correction pattern and the second simulation contour of the second correction pattern, obtained by the adjusted optical proximity correction model, is less than or equal to the threshold.

It may be understood that the sub-resolution assistant feature (SRAF) is to add some small patterns around the target pattern in the integrated circuit design layout to make the target pattern look like a dense pattern from the optical angle. These small patterns must be smaller than the resolution of the photolithography machine. During the exposure, these patterns just transmit light and will not be transferred to the photoresist.

In an embodiment, adjusting the optical proximity correction model further comprises:

adjusting a target value of the target pattern, if the difference value between the first simulation contour of the first correction pattern and the second simulation contour of the second correction pattern, obtained by the optical proximity correction model after multiple adjustments, is still greater than the threshold; and

correcting the optical proximity correction model again by the adjusted target value, until the difference value between the first simulation contour of the first correction pattern and the second simulation contour of the second correction pattern, obtained by the adjusted optical proximity correction model, is less than or equal to the threshold.

During the specific implementation, it may not be able to ensure that the difference value between the first simulation contour of the first correction pattern and the second simulation contour of the second correction pattern, obtained by the optical proximity correction model after multiple adjustments, is less than or equal to the threshold. In this case, if it is allowed by the process, the target value of the target pattern is adjusted. Then, the optical proximity correction model is corrected by the adjusted target value, so that the difference value between the first simulation contour of the first correction pattern and the second simulation contour of the second correction pattern, obtained by the adjusted optical proximity correction model, is less than or equal to the threshold. The photolithography process window is enlarged and the product yield is improved. Specifically, the target value of the target pattern includes, but is not limited to, the target value preset for the target pattern in the photolithography process step to be reached after photolithography, and may be the target value preset for the target pattern in the etching process step to be reached after etching.

Exemplarily, a certain target pattern is a linear convex or groove shape, and there is no other pattern within a certain distance from this shape (for example, the distance may be 1 μm, which may be set according to the actual photolithography conditions). In this case, this pattern may be regarded as an isolated pattern. Within the range allowed by the process, there may be EPE of 1 nm to 2 nm to make the PV band approach the standard conditions as much as possible, thereby ensuring a sufficient photolithography process window.

In an embodiment, adjusting the target value of the target pattern comprises:

calculating positional relationships between the target pattern and an upper pattern and/or a lower pattern; and

adjusting the target value according to the positional relationships.

It may be understood that a semiconductor device manufactured by a photolithography process generally comprises a plurality of film layers stacked together. By calculating the positional relationships between the target pattern and an upper pattern and/or a lower pattern, on the premise that the target pattern and the upper pattern and/or the lower pattern will not affect each other and if it is allowed by the process, the target value is adjusted so that the difference value between the first simulation contour of the first correction pattern and the second simulation contour of the second correction pattern is less than or equal to the threshold, thereby enlarging the photolithography process window.

In an embodiment, calculating the positional relationships between the target pattern and an upper pattern and/or a lower pattern comprises:

calculating distances between the boundary of the target pattern and the boundary of the upper pattern and/or the lower pattern overlapping with the target pattern.

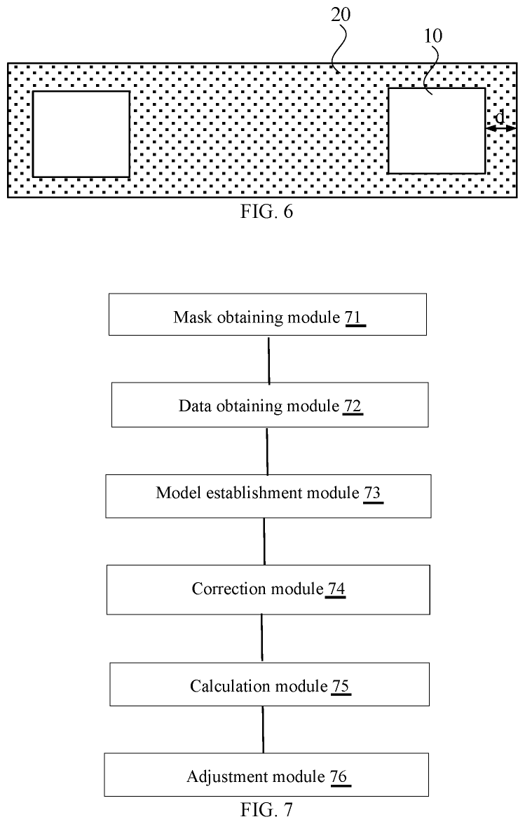

Exemplarily, FIG. 6 is a schematic structure diagram of a hole-shaped target pattern according to an embodiment of the present disclosure. Referring to FIG. 6, the hole 10 overlaps with the linear pattern 20 in the lower layer. Because the pattern after exposure and the pattern after photolithography may have a certain derivation, in order to ensure that the linear pattern 20 completely surrounds the hole 10, the boundary distance d between the two is generally set to be greater than 15 nm to 20 nm, so as to avoid poor electrical connection after photolithography.

In an embodiment, calculating the positional relationships between the target pattern and an upper pattern and/or a lower pattern further comprises:

calculating the distances between the boundary of the target pattern and the boundary of a pattern close to the upper pattern and/or the lower pattern overlapping with the target pattern.

It may be understood that, in the actual adjustment process, it is also necessary to consider the distances between the boundary of the target pattern and the boundary of a pattern close to the upper pattern and/or the lower pattern overlapping with the target pattern. For example, if the spacing between two patterns is less than the preset adjustment distance, the adjustment needs to be performed on the premise of avoiding overlapping of patterns in the same layer.

In an embodiment, adjusting the correction mode for the target pattern according to the difference value further comprises:

obtaining a simulation process window of the first correction pattern and a simulation process window of the second correction pattern; and

correcting the pattern by the optical proximity correction model, if the simulation process window of the first correction pattern is greater than or equal to the simulation process window of the second correction pattern and the difference value is less than or equal to a set threshold; and

correcting the pattern by the process variation band model, if the simulation process window of the first correction pattern is less than the simulation process window of the second correction pattern and the difference value is less than or equal to a set threshold.

It may be understood that correcting the pattern by a method that results in a large process window can effectively improve the product yield.

In an embodiment, adjusting the correction mode for the target pattern according to the difference value further comprises:

obtaining a simulation process window of the first correction pattern and a simulation process window of the second correction pattern; and

adopting the correction mode of the first simulation profile and the second simulation profile which one is closer to the target value of the target pattern, if the simulation process window of the first correction pattern is greater than or equal to the simulation process window of the second correction pattern, and the difference value is greater than a set threshold.

By using a correction mode that is closer to the target value of the target pattern, the error of the photolithography target may be made as small as possible, and the quality of the photolithography process may be improved.

An embodiment of the present disclosure further provides an optical proximity correction apparatus, comprising:

a mask obtaining module 71 configured to obtain a test mask;

a data obtaining module 72 configured to obtain wafer data under current photolithography conditions by the test mask; and

a model establishment module 73 configured to establish an optical proximity correction model and a process variation band model by the wafer data.

In an embodiment, the model establishment module is specifically configured to:

obtain optical system relevant parameters, mask relevant parameters, photolithography target film layer relevant parameters and wafer data under the current photolithography conditions to establish the optical proximity correction model; and

establish the process variation band model according to the wafer data of a focus energy matrix and data of the current photolithography conditions.

In an embodiment, the wafer data of the focus energy matrix comprises wafer data obtained by an exposure and focal depth matrix, which is formed by taking the standard exposure and the standard focal depth as the center, and then respectively extending in positive and negative directions by a preset exposure step size and a preset focal depth step size.

The apparatus further comprises a correction module 74 configured to correct a target pattern according to the optical proximity correction model and the process variation band model to obtain a first correction pattern and a second correction pattern respectively;

a calculation module 75 configured to calculate a difference value between a first simulation contour of the first correction pattern and a second simulation contour of the second correction pattern; and

an adjustment module 76 configured to adjust the correction mode for the target pattern according to the difference value.

In an embodiment, the apparatus may further comprise a mask fabrication module, configured to fabricate a test mask.

In an embodiment, the adjustment module is specifically configured to:

set a threshold;

correct the target pattern by the optical proximity correction model, if the difference value is less than or equal to a threshold; and

adjust the optical proximity correction model, and correct the target pattern by the adjusted optical proximity correction model, if the difference value is greater than the threshold.

By the technical solutions of this embodiment, by the mask fabrication module, a test mask is fabricated, and photolithography tests are performed by using the test mask; by the data obtaining module, wafer data under current photolithography conditions is obtained by the test mask; by the model establishment module, an optical proximity correction model and a process variation band model are established by the wafer data; by the correction module, a target pattern is corrected according to the optical proximity correction model and the process variation band model to obtain a first correction pattern and a second correction pattern respectively; by the calculation module, a difference value between a first simulation contour of the first correction pattern and a second simulation contour of the second correction pattern is calculated; and by the adjustment module, the correction mode for the target pattern is adjusted according to the difference value. The possible variations caused by the process variation band are considered during the optical proximity correction, the insufficient photolithography process window during the existing correction is overcome, the photolithography process window is enlarged, and the product yield is improved.

In an embodiment, adjusting the optical proximity correction model comprises:

adjusting the optical proximity correction model by changing a sub-resolution assistant feature and/or re-sizing the pattern, until the difference value between the first simulation contour of the first correction pattern and the second simulation contour of the second correction pattern, obtained by the adjusted optical proximity correction model, is less than or equal to the threshold.

In an embodiment, adjusting the optical proximity correction model further comprises:

adjusting a target value of the target pattern, if the difference value between the first simulation contour of the first correction pattern and the second simulation contour of the second correction pattern, obtained by the optical proximity correction model after multiple adjustments, is still greater than the threshold; and

correcting the optical proximity correction model again by the adjusted target value, until the difference value between the first simulation contour of the first correction pattern and the second simulation contour of the second correction pattern, obtained by the adjusted optical proximity correction model, is less than or equal to the threshold.

In an embodiment, adjusting the target value of the target pattern comprises:

calculating the positional relationships between the target pattern and an upper pattern and/or a lower pattern; and

adjusting the target value according to the positional relationships.

In an embodiment, the calculating the positional relationships between the target pattern and an upper pattern and/or a lower pattern comprises:

calculating the distances between the boundary of the target pattern and the boundary of the upper pattern and/or the lower pattern overlapping with the target pattern.

In an embodiment, the calculating the positional relationships between the target pattern and an upper pattern and/or a lower pattern further comprises:

calculating the distances between the boundary of the target pattern and the boundary of a pattern close to the upper pattern and/or the lower pattern overlapping with the target pattern.

In an embodiment, the adjustment module is further configured to:

obtaining a simulation process window of the first correction pattern and a simulation process window of the second correction pattern; and

correcting the pattern by the optical proximity correction model, if the simulation process window of the first correction pattern is greater than or equal to the simulation process window of the second correction pattern and the difference value is less than or equal to a set threshold; and

correcting the pattern by the process variation band model, if the simulation process window of the first correction pattern is less than the simulation process window of the second correction pattern and the difference value is less than or equal to a set threshold.

In an embodiment, the adjustment module is further configured to:

obtaining a simulation process window of the first correction pattern and a simulation process window of the second correction pattern; and

adopting the correction mode of the first simulation profile and the second simulation profile which one is closer to the target value of the target pattern, if the simulation process window of the first correction pattern is greater than or equal to the simulation process window of the second correction pattern, and the difference value is greater than a set threshold.

Note that the foregoing descriptions are only preferred embodiments of the present disclosure and the technical principles applied. It may be understood by those skilled in the art that the present disclosure is not limited to the specific embodiments described herein, and various apparent changes, adjustments and substitutions can be made without departing from the protection scope of the present disclosure. Therefore, although the present disclosure has been described in detail by the above embodiments, the present disclosure is not limited to those embodiments and can comprise more other equivalent embodiments without departing from the concept of the present disclosure. The scope of the present disclosure is defined the appended claims.

1. An optical proximity correction method, comprising:
obtaining a test mask;
obtaining wafer data under current photolithography conditions by the test mask;
establishing an optical proximity correction model and a process variation band model by the wafer data;
correcting a target pattern according to the optical proximity correction model and the process variation band model to obtain a first correction pattern and a second correction pattern respectively;
calculating a difference value between a first simulation contour of the first correction pattern and a second simulation contour of the second correction pattern; and
adjusting a correction mode for the target pattern according to the difference value.

2. The optical proximity correction method according to claim 1, wherein the adjusting the correction mode for the target pattern according to the difference value comprises:
correcting the target pattern by the optical proximity correction model, if the difference value is less than or equal to a threshold; and
adjusting the optical proximity correction model, and correcting the target pattern by the adjusted optical proximity correction model, if the difference value is greater than the threshold.

3. The optical proximity correction method according to claim 2, wherein the adjusting the optical proximity correction model comprises:
adjusting the optical proximity correction model by changing a sub-resolution assistant feature and/or re-sizing the pattern, until the difference value between the first simulation contour of the first correction pattern and the second simulation contour of the second correction pattern, obtained by the adjusted optical proximity correction model, is less than or equal to the threshold.

4. The optical proximity correction method according to claim 3, further comprising:
adjusting a target value of the target pattern, if the difference value between the first simulation contour of the first correction pattern and the second simulation contour of the second correction pattern, obtained by the optical proximity correction model after multiple adjustments, is still greater than the threshold; and
correcting the optical proximity correction model again by the adjusted target value, until the difference value between the first simulation contour of the first correction pattern and the second simulation contour of the second correction pattern, obtained by the adjusted optical proximity correction model, is less than or equal to the threshold.

5. The optical proximity correction method according to claim 4, wherein the adjusting a target value of the target pattern comprises:
calculating positional relationships between the target pattern and an upper pattern and/or a lower pattern; and
adjusting the target value according to the positional relationships.

6. The optical proximity correction method according to claim 5, wherein the calculating the positional relationships between the target pattern and an upper pattern and/or a lower pattern comprises:
calculating distances between the boundary of the target pattern and the boundary of the upper pattern and/or the lower pattern overlapping with the target pattern.

7. The optical proximity correction method according to claim 6, wherein the calculating the positional relationships between the target pattern and an upper pattern and/or a lower pattern further comprises:
calculating the distances between the boundary of the target pattern and the boundary of a pattern close to the upper pattern and/or the lower pattern overlapping with the target pattern.

8. The optical proximity correction method according to claim 1, wherein the adjusting the correction mode for the target pattern according to the difference value further comprises:
obtaining a simulation process window of the first correction pattern and a simulation process window of the second correction pattern;
correcting the target pattern by the optical proximity correction model, if the simulation process window of the first correction pattern is greater than or equal to the simulation process window of the second correction pattern and the difference value is less than or equal to the set threshold; and
correcting the target pattern by the process variation band model, if the simulation process window of the first correction pattern is less than the simulation process window of the second correction pattern and the difference value is less than or equal to the set threshold.

9. The optical proximity correction method according to claim 1, wherein the adjusting the correction mode for the target pattern according to the difference value further comprises:
obtaining a simulation process window of the first correction pattern and a simulation process window of the second correction pattern; and
adopting the correction mode of the first simulation profile and the second simulation profile which one is closer to the target value of the target pattern, if the simulation process window of the first correction pattern is greater than or equal to the simulation process window of the second correction pattern, and the difference value is greater than the set threshold.

10. The optical proximity correction method according to claim 1, wherein the establishing the optical proximity correction model and the process variation band model by the wafer data comprises:
obtaining optical system relevant parameters, mask relevant parameters, photolithography target film layer relevant parameters and wafer data under the current photolithography conditions to establish the optical proximity correction model; and
establishing the process variation band model according to the wafer data of a focus energy matrix and data of the current photolithography conditions.

11. The optical proximity correction method according to claim 10, wherein the wafer data of the focus energy matrix comprises wafer data obtained by an exposure and focal depth matrix, which is formed by taking the standard exposure and the standard focal depth as the center, and then respectively extending in positive and negative directions by a preset exposure step size and a preset focal depth step size.

12. An optical proximity correction apparatus, comprising:
a mask obtaining module, configured to obtain a test mask;
a data obtaining module, configured to obtain wafer data under current photolithography conditions by the test mask;
a model establishment module, configured to establish an optical proximity correction model and a process variation band model by the wafer data;
a correction module, configured to correct a target pattern according to the optical proximity correction model and the process variation band model to obtain a first correction pattern and a second correction pattern respectively;
a calculation module, configured to calculate a difference value between a first simulation contour of the first correction pattern and a second simulation contour of the second correction pattern; and
an adjustment module, configured to adjust the correction mode for the target pattern according to the difference value.
